(19) United States
(12) Patent Application Publication
(10) Pub. No.: US 2013/0020669 A1
(43) Pub. Date: Jan. 24, 2013

(54) METHOD FOR MANUFACTURING SEMICONDUCTOR DEVICE, RESIN SEALING APPARATUS, AND SEMICONDUCTOR DEVICE

(71) Applicant: Masanori Koga, Fukuoka (JP)

(72) Inventor: Masanori Koga, Fukuoka (JP)

(73) Assignee: ASAHI ENGINEERING K. K., Kurume-shi, Fukuoka (JP)

(21) Appl. No.: 13/522,440

(22) PCT Filed: Apr. 13, 2011
(86) PCT No.: PCT/JP2011/059172

§ 371 Date: Jul. 16, 2012

(51) Int. Cl. H01L 31/0203; H01L 21/56; H01L 31/18

(52) U.S. Cl. 257/433; 438/64; 264/272.17; 257/E31.117

(57) ABSTRACT

When a resin sealed package is molded with use of a release film for the purpose of preventing generation of a flash on a surface of a seal glass, the seal glass may be broken by being compressed and bent by the release film at a portion of the seal glass below which there is a cavity. The present invention prevents this breakage of the seal glass. More specifically, the present invention prevents breakage of the seal glass by forming a recess corresponding to a compression allowance of the release film at a mold die above the portion of the seal glass below which there is the cavity, or at the seal glass itself, and thereby releasing a pressure from the release film.

### TECHNICAL FIELD

The present invention relates to a method for manufacturing a semiconductor device, and in particular, to a method for manufacturing a semiconductor device, in which a resin is molded on a semiconductor device having a cavity inside a seal glass thereof while protecting the seal glass with a release film.

Further, the present invention relates to a semiconductor device, and in particular, to a semiconductor device having a cavity inside a seal glass thereof, on which a resin is molded while the seal glass is protected with a release film.

Further, the present invention relates to a resin sealing apparatus, and in particular, to a resin sealing apparatus for molding a resin on a semiconductor device having a cavity inside a seal glass thereof while protecting the seal glass with a release film.

Further, the present invention relates to a semiconductor device in which a light-receiving area formed on a semiconductor chip is air-tightly sealed by a seal glass, and a method for manufacturing the same.

### BACKGROUND ART

In recent years, growing demand for improvement in the performance of electronic apparatuses and reductions in the weight, thickness, length, and size of electronic apparatuses has led to development of highly densely integrated electronic parts and highly densely packed electronic parts. Even electronic parts such as a CCD (Charge Coupled Device) image sensor and a CMOS (Complementary Metal Oxide Semiconductor) image sensor, which conventionally used to be formed as a relatively large package, have been becoming available as a CSP (chip size package). One of especially widespread types of chip size packages is a chip size package having a hollow structure constructed by directly disposing a seal glass on an active surface side of a sensor chip with use of a rib member or spacer.

A process for manufacturing such a CSP employs a so-called film molding method of molding a resin on a semiconductor device while protecting a seal glass with a release film so as to prevent generation of a thin flash at the seal glass during a resin molding process. At this time, while the release film is compressed at the seal glass above the rib member or spacer, the release film is not compressed but is pressed to push the seal glass above the hollow space, whereby the seal glass may be bent and eventually broken.

One conventional method to prevent the seal glass from being bent to be broken during the resin molding process is to dispose a support frame 15 around a cover glass (seal glass) 14 to make the support frame receive a pressing pressure applied from an upper-side mold die 68 to the cover glass 14, thereby preventing the cover glass 14 from being bent, as discussed in PTL 1.

However, the method discussed in PTL 1 requires the support frame to be disposed around the seal glass, thereby requiring preparation of a space therefore, leading to the possibility of an increase in the size of the semiconductor device. Further, the necessity of additional cost for the provision of the support frame and an additional process for mounting the support frame may result in an increase in the manufacturing cost of the semiconductor device.

PTL 1: Japanese Patent Application Public Disclosure No. 2008-47665 (paragraph 0045 and FIG. 11)

### SUMMARY OF INVENTION

### Technical Problem

The present invention has been contrived in consideration of the above-described problem in the conventional technique, and an object thereof is to provide a method for manufacturing a semiconductor device in which a resin is molded on a semiconductor device having a cavity inside a seal glass thereof while protecting the seal glass with a release film, characterized in that it is possible to prevent generation of a flash at the seal glass and breakage of the seal glass due to bending of the seal glass while reducing increases in the size and cost of the semiconductor device.

### Solution to Problem

According to one aspect of the present invention, a release film (mold die release film) is pressed only at a portion thereof right above a rib member or spacer supporting a seal glass in order to prevent breakage of the seal glass. In a package having a hollow structure constructed by directly disposing the seal glass on an active surface side of a sensor chip with use of the rib member or spacer, structurally, there is a cavity below a central portion of the seal glass. Therefore, nothing can receive a pressure of the release film, and the seal glass has to receive the film pressure. As a result, the pressure from the release film exceeds the strength of the seal glass, whereby the seal glass may be broken. To solve this problem, a film escape recess is formed at an upper die above a portion of the seal glass below which there is a cavity, in order to allow an escape of the release film pressure applied to the central portion of the seal glass toward a mold die cavity side. Due to the provision of this recess, a semiconductor device is clamped by a mold die to mold a resin on the semiconductor device while the release film is prevented from applying a pressure to the seal glass above the cavity. As a result, it is possible to limit the portion where the release film is pressed to the portion above the rib member or spacer, which is a support structure of the seal glass. In other words, it is possible to reduce or prevent application of a bending stress to the seal glass by forming the film escape recess at the mold die cavity side so that the pressure of the release film is not applied to the central portion of the seal glass, whereby it is possible to prevent breakage of the seal glass. According to this structure, it is possible to clamp the semiconductor device by the mold die at a pressure capable of preventing generation of a thin flash while preventing breakage of the seal glass without adding another member such as the support frame.

A method for manufacturing a semiconductor device according to the one aspect of the present invention is a method for manufacturing a semiconductor device, in which a resin is molded on a semiconductor device having a cavity (109) inside a seal glass (108) thereof while protecting the seal glass (108) with a release film (110). This method is characterized in that, when the semiconductor device is clamped by a mold die (100), the release film (110) escapes into a film escape area (104a; 104b; 104c) formed at the mold die (100) or the seal glass (108) above the cavity while the resin is molded on the semiconductor device. As one example, the film escape area corresponds to an area occupied by the cavity (109). Alternatively, the film escape area may be smaller than the area occupied by the cavity as long as a pressure applied to the seal glass above the cavity falls within an allowable range. Further alternatively, the film escape area may be larger than the area occupied by the cavity as long as it is possible to prevent generation of a thin flash at the seal glass.

According to this method for manufacturing a semiconductor device, when the semiconductor device is clamped by the mold die, it is possible to reduce or prevent application of a bending stress on the seal glass above the cavity by allowing an escape of the release film into the film escape area above the cavity. As a result, it is possible to prevent the seal glass from being bent above the cavity inside the seal glass, thereby preventing the seal glass from being broken. Therefore, it is possible to mold the resin on the semiconductor device while clamping the semiconductor device by the mold die at a pressure capable of preventing generation of a thin flash at the seal glass while preventing breakage of the seal glass. Further, since the film escape area is formed at the mold die or the seal glass, it is possible to reduce or prevent increases in the size and cost of the semiconductor device, compared to the conventional technique providing another member such as support frame around the seal glass.

A resin sealing apparatus according to another aspect of the present invention is a resin sealing apparatus for molding a resin on a semiconductor device having a cavity (109) inside a seal glass (108) thereof while protecting the seal glass (108) of the semiconductor device with a release film (110). This apparatus is characterized in that, for allowing an escape of the release film (110) when the semiconductor device is clamped by a mold die (100), a film escape recess (104a) is formed at the mold die (100) so as to at least partially overlap an area occupied by the cavity (109). As one example, an area occupied by the film escape recess (104a) corresponds to the area occupied by the cavity (109). Alternatively, the area occupied by the film escape recess may be smaller than the area occupied by the cavity as long as a pressure applied to the seal glass above the cavity falls within an allowable range. Further alternatively, the area occupied by the film escape recess may be larger than the area occupied by the cavity as long as it is possible to prevent generation of a thin flash at the seal glass. According to this mold die, since the film escape area is formed at the mold die itself, it is possible to mold a resin on the semiconductor device while clamping the semiconductor device by the mold die at a pressure capable of preventing breakage of the seal glass and generation of a thin flash, with use of the method capable of reducing or preventing an increase in the size of the semiconductor device.

A semiconductor device according to still another aspect of the present invention is a semiconductor device having a cavity (109) inside a seal glass (108), and manufactured by molding a resin on it while protecting the seal glass (108) with a release film (110). This semiconductor device is characterized in that, for allowing an escape of the release film (110) when the semiconductor device is clamped by a mold die, a film escape area (104b, 104c) is formed at the seal glass (108) so as to at least partially overlap an area occupied by the cavity (109). As one example, an area occupied by the film escape area (104b; 104c) corresponds to the area occupied by the cavity (109). Alternatively, the film escape area may be smaller than the area occupied by the cavity as long as a pressure applied to the seal glass above the cavity falls within an allowable range. Further alternatively, the film escape area may be larger than the area occupied by the cavity as long as it is possible to prevent generation of a thin flash at the seal glass. According to this semiconductor device, since the film escape area is formed at the seal glass itself, it is possible to mold a resin on the semiconductor device while clamping the semiconductor device by the mold die at a pressure capable of preventing breakage of the seal glass and generation of a thin flash, with use of the method capable of reducing or preventing an increase in the size of the semiconductor device.

It is preferable that the depth of the film escape area is equal to or greater than a compression allowance by which the release film (110) is compressed at the portion other than the cavity (109) when the semiconductor device is clamped by the mold die (100).

The film escape area can be provided as the film escape recess (104a) formed at the mold die (100).

The film escape area can be provided as the film escape recess (104b) formed at a surface of the seal glass (108) closer to the release film (110).

The film escape area can be also realized by disposing a member (111) having a predetermined thickness at the surface of the seal glass (108) closer to the release film (110) so as to surround at least a part of the area corresponding to the cavity (109), and setting the portion surrounded by the member (111) as the film escape area. The member having the predetermined thickness can be embodied by, for example, a film (111) more rigid than the release film. In this case, it is possible to form the film escape area while preventing an increase in the size of the device by providing a thin member such as a film to an existing seal glass.

For example, the seal glass (108) is disposed on the semiconductor chip via the rib member or spacer (107), whereby the cavity (109) of the semiconductor device is defined.

The semiconductor device includes an image sensor such as a CCD images sensor or a CMOS image sensor.

### BRIEF DESCRIPTION OF THE DRAWINGS

FIG. 1 is a cross-sectional view illustrating a semiconductor device placed on a mold die of a resin sealing apparatus during execution of a method for manufacturing a semiconductor device according to a first embodiment of the present invention;

FIG. 2 is a cross-sectional view illustrating the semiconductor device illustrated in FIG. 1 with the mold die closed;

FIG. 3 is a cross-sectional view illustrating a semiconductor device placed on a mold die of a resin sealing apparatus during execution of a method for manufacturing a semiconductor device according to a comparative example;

FIG. 4 is a cross-sectional view illustrating the semiconductor device illustrated in FIG. 3 with the mold die closed;

FIG. 5 illustrates a comparison between pressure application to a seal glass with a film escape recess formed on the mold die and pressure application to a seal glass without a film escape recess formed on the mold die;

FIG. 6 is an enlarged cross-sectional view illustrating a semiconductor device placed on a mold die of a resin sealing apparatus during execution of a method for manufacturing a semiconductor device according to a second embodiment of the present invention, illustrating how a release film is compressed and how a seal glass is bent when the seal glass of the semiconductor device has a film escape recess;

FIG. 7 is an enlarged cross-sectional view illustrating a semiconductor device placed on a mold die of a resin sealing apparatus during execution of a method for manufacturing a semiconductor device according to a comparative example, illustrating how a release film is compressed and how a seal glass is bent when the seal glass of the semiconductor device does not have a film escape recess; and

FIG. 8 is an enlarged cross-sectional view illustrating a mold die and a semiconductor device with a film escape area defined from a portion surrounded by a spacer material disposed at the periphery of a seal glass, according to a modification of the second embodiment.

### DETAILED DESCRIPTION OF THE PREFERRED EMBODIMENTS

### First Embodiment

To achieve the above-described object, a method for manufacturing a semiconductor device according to an embodiment of the present invention is characterized in that a film escape recess is formed at a cavity of an upper die, thereby preventing generation of a bending stress at a portion of a seal glass below which there is a cavity, due to a pressure of a release film. A reason for breakage of the seal glass is that a bending stress is generated at the seal glass by a pressure generated when the film is pressed against the central portion of the seal glass due to the presence of the cavity below the seal glass. Therefore, since prevention of generation of a bending stress at the seal glass can be realized by avoiding pressing the release film above the cavity, a film escape recess is formed at the mold die above the cavity to allow an escape of the release film. Due to this structure, when a package (semiconductor device) having a hollow structure is clamped via the release film, the release film is compressed above a rib member or spacer, but the release film escapes upward at the film escape recess, thereby preventing application of a pressure to the seal glass to prevent generation of a bending pressure. As a result, it is possible to mold a resin on the semiconductor device by clamping the semiconductor device by the mold die at a pressure capable of preventing generation of a thin flash while preventing breakage of the seal glass.

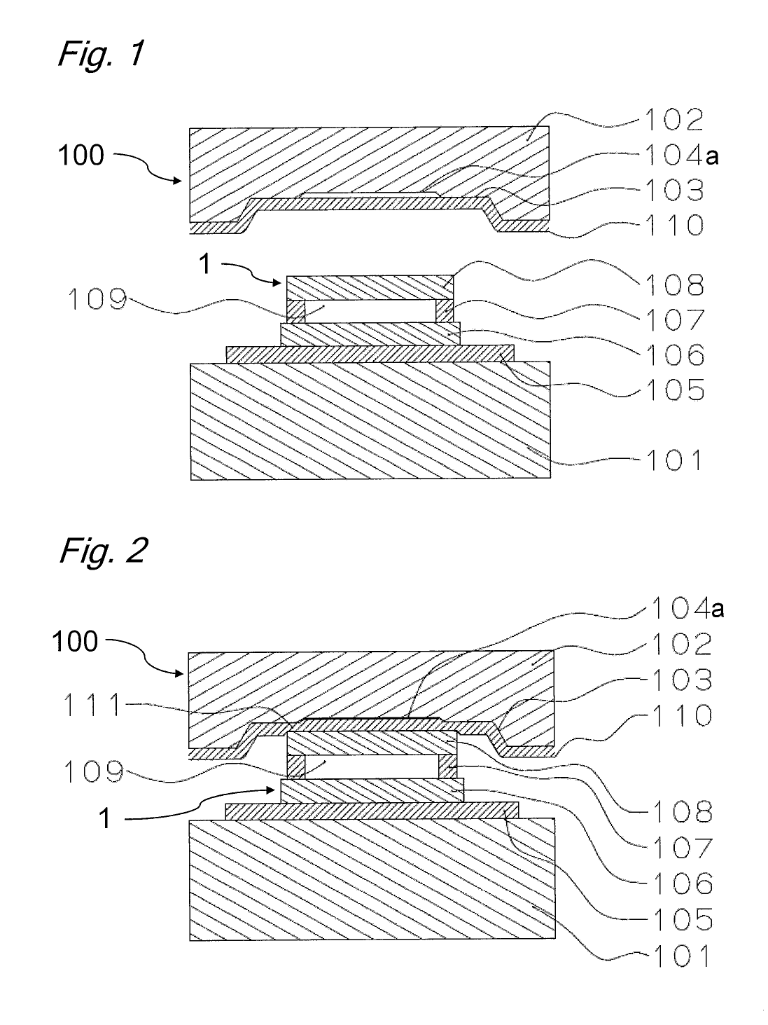

FIG. 1 is a cross-sectional view illustrating a semiconductor device 1 placed on a mold die 100 of a resin sealing apparatus during execution of a method for manufacturing a semiconductor device according to an embodiment of the present invention. FIG. 2 illustrates the semiconductor device 1 illustrated in FIG. 1 with the mold die 100 closed.

The mold die 100 is constituted by a lower die 101 and an upper die 102. A cavity 103 is formed at the bottom surface of the upper die 102. A film escape recess 104a is formed at the bottom surface of the cavity 103 over an area corresponding to a cavity 109 inside a seal glass 108 of the semiconductor apparatus 1. This film escape recess 104a has an area corresponding to the cavity 109 in a planar view, and has a depth equal to or greater than an amount by which the thickness of a release film (mold release film) 110 is reduced by being compressed when the semiconductor apparatus 1 is clamped between the upper die 102 and the lower die 103, i.e., a depth equal to or greater than a value of a compression allowance (for example, a depth of approximately 0.3 mm to approximately 0.5 mm).

Alternatively, the depth of the film escape recess 104a may be smaller than the value of the compression allowance as long as a pressure applied from the release film 110 to the seal glass 108 above the cavity 109 falls within an allowable range during a clamping process (a pressure range capable of preventing breakage of the seal glass).

Further, although it is preferable that the film escape recess 104 has an area corresponding to the area of the cavity 109 in a planar view, the area of the film escape recess 104 may be smaller than the area of the cavity 109 as long as a pressure applied from the release film 110 to the seal glass 108 above the cavity 109 falls within an allowable range during a clamping process. Further, the area of the film escape recess 104a may overlap an area occupied by a rib member or spacer 107 in a planar view as long as it is possible to prevent generation of a thin flash at the seal glass 108.

The semiconductor device 1 is a chip size package (CSP) having a hollow structure constructed by directly disposing the seal glass 108 on an active surface side of a sensor chip 106 with use of the rib member or spacer 107 to form a hollow structure. This semiconductor device 1 includes a substrate 105 as a wiring board, a sensor chip (semiconductor chip) 106 fixed on the substrate 105, and the seal glass 108 supported by the rib member or spacer 107 on the sensor chip 106 and disposed with a predetermined space maintained between the seal glass 108 and the sensor chip 106.

Although not illustrated, the substrate 105 includes an internal conductor pad (an upper surface side) and an external conductor pad (a lower surface side) between which conduction is established via a through-hole. The internal conductor pad is connected to the sensor chip 106 via a bonding wire. The sensor chip 106 has an active surface including a light-receiving area where an element such as a CCD (Charge Coupled Device) image sensor or a CMOS (Complementary Metal Oxide Semiconductor) image sensor is formed, and includes an input/output pad (not illustrated) used for the connection with the substrate 105 via the bonding wire. The rib member or spacer 107 is a frame member having a predetermined thickness, and is fixed to the periphery of the active surface so as to surround the active surface of the sensor chip 106. The seal glass 108 is fixed on the rib member or spacer 107, and air-tightly seals the sensor chip 106 together with the rib member or spacer 107. As configured in this way, the cavity 109 is formed between the sensor chip 106 and the cover glass 108.

The above-described mold die 100 is used in resin molding in the following manner. The release film 110 is attached in the cavity 103 of the upper die 102, and the semiconductor device 1 is placed in the lower die 101 (FIG. 1). After that, the mold die 100 is closed so that the semiconductor device 1 is clamped between the lower die 101 and the upper die 102 (FIG. 2). In this state, the release film 110 is closely attached to the seal glass 108 of the semiconductor device 1 to thereby protect the seal glass 108. More specifically, during a resin molding process, resin is prevented from entering on the seal glass 108, and the release film 110 is closely attached to the seal glass 108 at a pressure capable of preventing generation of a thin flash at the seal glass 108. Then, a resin is supplied into the cavity 103 by, for example, the transfer mold method, thereby providing a resin seal on the semiconductor device 100.

When the semiconductor device 1 is clamped by the mold die 100, a pressing pressure is applied from the bottom surface of the cavity 103 to the seal glass 108 via the release film 110. At this time, at the portion of the seal glass 108 above the rib member or spacer 107, the release film 110 and the seal glass 108 are sandwiched between the bottom surface of the cavity 103 and the rib member or spacer 107, so that the release film 110 is compressed by a pressing pressure from the cavity 103, and a pressing force is applied from the release film 110 to the seal glass 108.

On the other hand, at a portion of seal glass 108 other than the portion above the rib member or spacer 107 (a portion above the cavity 109), the release film 110 faces the film escape recess 104a formed at the bottom surface of the cavity 103, and is not compressed since the release film 110 escapes into the film escape recess 10a. Accordingly, above the cavity 109, the release film 110 does not transmit the pressing pressure from the bottom surface of the cavity 103 to the seal glass 108, and therefore a bending stress is not applied to the seal glass 108. As a result, it is possible to prevent breakage of the seal glass 108 by receiving the bending stress above the cavity 109.

### Comparative Example

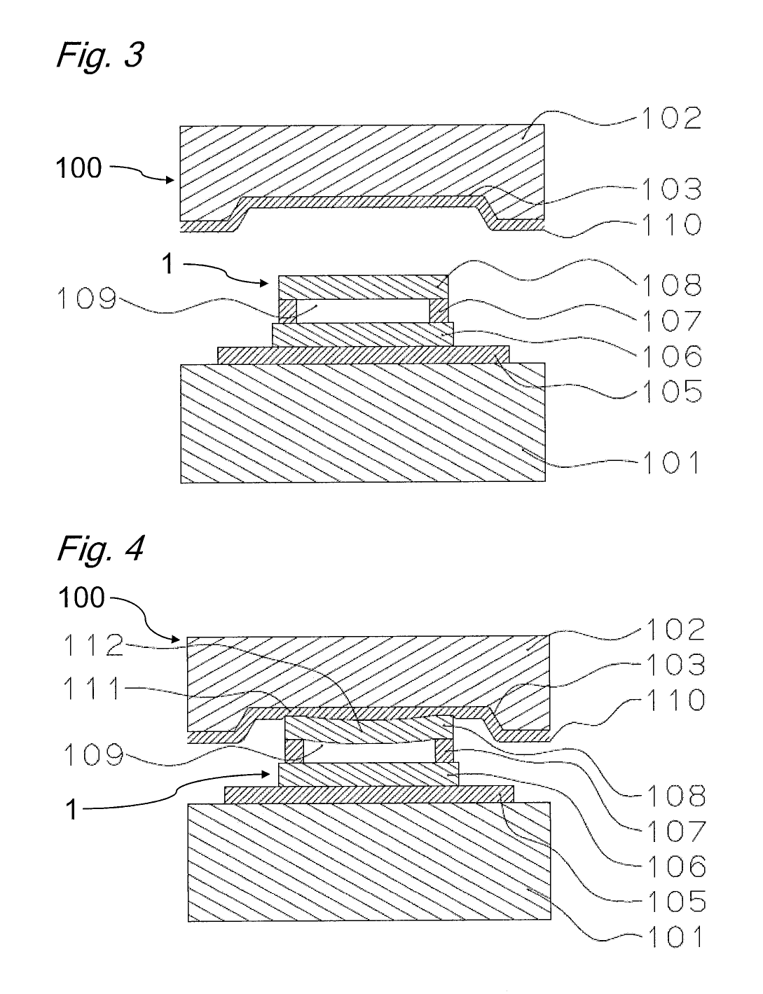

FIG. 3 is a cross-sectional view illustrating a semiconductor device placed on a mold die of a resin sealing apparatus during execution of a method for manufacturing a semiconductor device according to a comparative example to be compared with the method for manufacturing a semiconductor device according to the present invention. According to the comparative example, the mold die 100 does not include the film escape recess 104a at the die cavity 103. FIG. 4 is a cross-sectional view of the semiconductor device illustrated in FIG. 3 with the mold die closed. According to this comparative example, the mold die 100 is configured in such a manner that the upper die 102 does not include a film escape recess at an area corresponding to the cavity 109 under the seal glass 108. Therefore, the seal glass 108 receives a pressure from the bottom surface of the cavity 103 via the release film 110 even above the cavity 109. As a result, a large bending stress is applied to the seal glass 108 above the cavity 109, so that the seal glass 108 is largely bent toward the inside of the cavity 109. Application of a bending stress stronger than the strength of the seal glass 108 results in a problem of a damage such as breakage of the seal glass 108.

On the other hand, according the method for manufacturing a semiconductor device of the present embodiment, when the semiconductor device 1 is clamped by the mold die 100, the release film 100 is closely attached to the seal glass 108 to protect the seal glass 108 at a predetermined pressure above the rib member or spacer 107. On the other hand, the release film 110 escapes into the film escape recess 104a at the portion above the cavity 109, which prevents the seal glass 108 from being bent by receiving the bending stress at the portion above the cavity 109, thereby preventing the breakage of the seal glass 108. In this way, the semiconductor device 1 can be clamped by the mold die 100 to mold a resin on the semiconductor device 1 (resin sealing) at a pressure capable of preventing breakage of the seal glass 108 and preventing generation of a thin flash. As a result, it is possible to improve the yield rate of the semiconductor device.

Further, according to the method for manufacturing a semiconductor device of the present embodiment, the film escape recess 104a is formed at the mold resin 100, whereby it is possible to reduce the size and cost of the semiconductor device 1 compared to the conventional technique using, for example, the support frame around the seal glass 108.

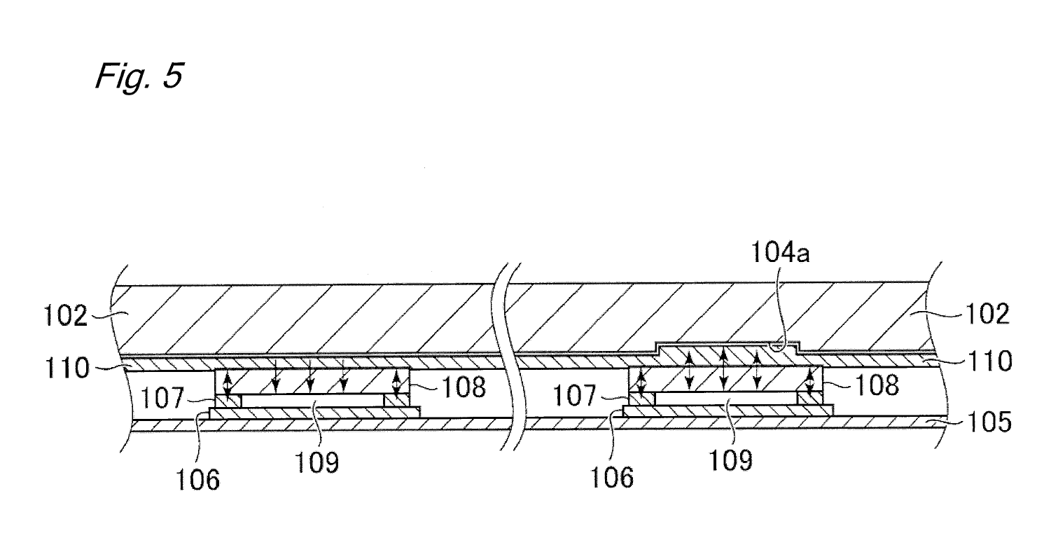

FIG. 5 illustrates how a bending stress is applied to the seal glass 108 when the semiconductor device 1 is clamped by the mold die 102 as the mold die according to the present embodiment (the right side in FIG. 5) and the mold die according to the comparative example (the left side in FIG. 5). As illustrated in the left side in FIG. 5, regarding the mold die according to the comparative example, the release film 110 is compressed above the rib member or spacer 107 by receiving a force applied from the upper die 102 downward to the seal glass 108 via the release film 110, and a force applied from the rib member or spacer 107 upward. On the other hand, the portion of the seal glass 108 above the cavity 109 receives only a force applied from the upper die 102 and the release film 110 downward, but there is no force applied upward. Therefore, as mentioned before, the central portion of the seal glass 108 receives a bending stress so as to be largely bent downward toward the cavity 109, whereby the seal glass 108 is subject to the risk of breakage. On the other hand, according to the mold die 100 of the present embodiment as illustrated in the right side of FIG. 5, due to the provision of the film escape recess 104a at the upper mold die 102, the release film 110 escapes into the film escape recess 104a above the cavity 109, thereby preventing the seal glass 108 from being compressed by the release film 110 above the cavity 109. Therefore, the seal glass 108 does not receive a downwardly applied bending stress above the cavity 109, and therefore the seal glass 108 is prevented from being largely bent.

According to the present embodiment, it is possible to allow an escape of the release film 110 into the film escape recess 104a formed at the mold die 100 to prevent a pressure due to a clamping operation from being applied to the portion of the seal glass 108 corresponding to the cavity 109, thereby reducing application of a bending stress to the seal glass 108. Therefore, the semiconductor device 1 can be clamped by the mold die 100 at a pressure capable of preventing breakage of the seal glass 108 and generation of a thin flash. Further, since the film escape recess 104a is formed at the mold die 100, it is possible to prevent increases in the size and cost of the semiconductor device 1, compared to the conventional technique including another member such as a support frame disposed around the seal glass 108.

### Second Embodiment

In the above-described embodiment, the film escape recess 104a is formed at the mold die 100. Alternatively, the semiconductor device 1 may be configured in such a manner that the release film 110 escapes toward the seal glass 108 at the portion of the release film 110 corresponding to the cavity 109 by forming a step approximately 0.3 mm to 0.5 mm high between the portion of the seal glass 108 corresponding to the cavity 109 and the portion of the seal glass 108 surrounding it. The step can be formed by slightly cutting or scraping the central portion of the seal glass 108 (the portion corresponding to the cavity 109) to reduce the thickness thereof, or attaching, for example, a more rigid film (for example, a polyimide film) than the release film 110 at the periphery of the seal glass 108. According to this structure, it is possible to reduce or prevent application of a bending stress to the seal glass 108 since the release film 110 escapes toward the seal glass 108 at the central portion of the seal glass 108, even through the release film 110 is compressed at the periphery of the seal glass 108.

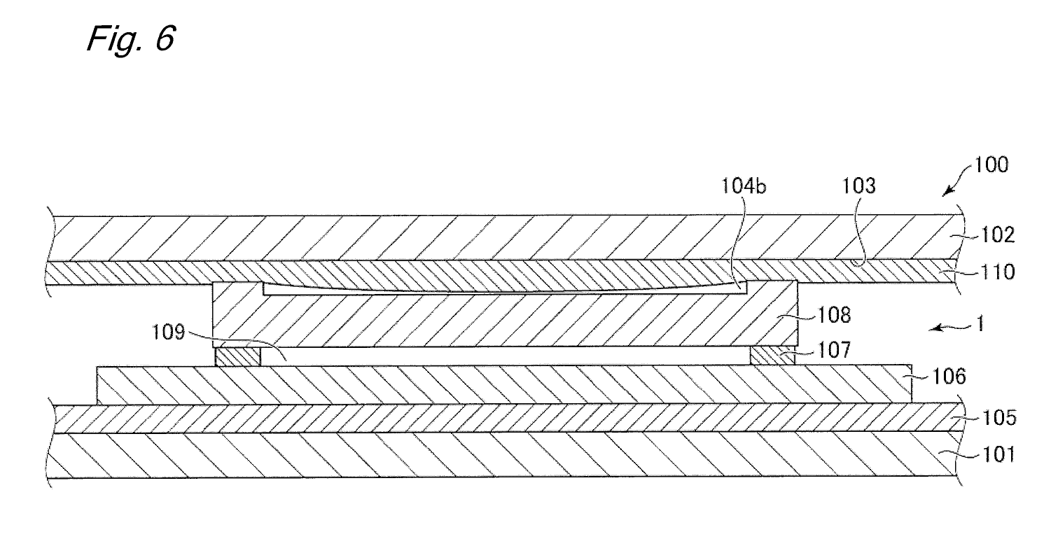

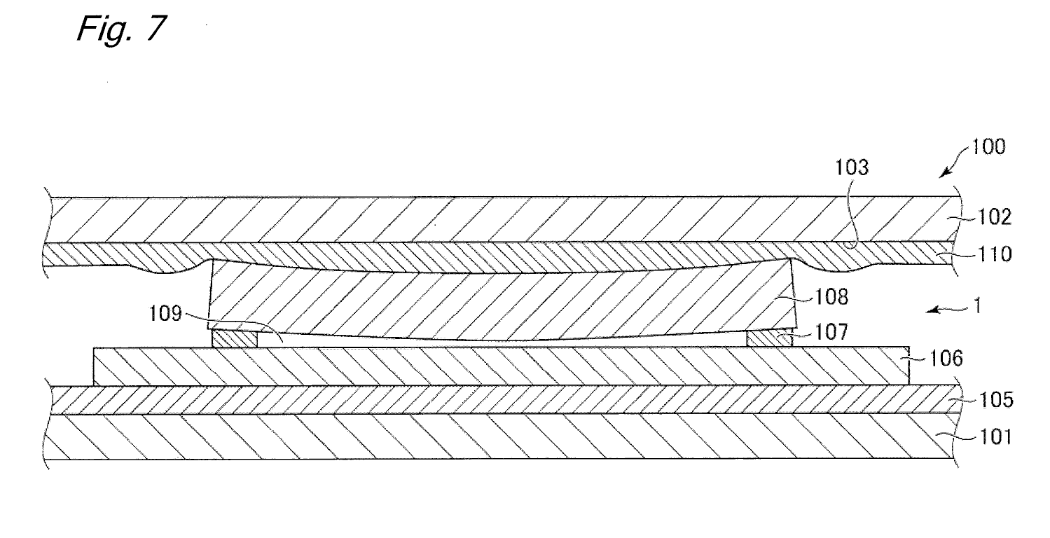

FIG. 6 is an enlarged cross-sectional view illustrating a semiconductor device placed at a mold die of a resin sealing apparatus during execution of a method for manufacturing a semiconductor device according to a second embodiment of the present invention. FIG. 7 is an enlarged cross-sectional view illustrating a semiconductor device placed at a mold die of a resin sealing apparatus during execution of a method for manufacturing a semiconductor device according to a comparative example, illustrating how a film is compressed and how a glass is bent without the film escape recess.

According to the comparative example illustrated in FIG. 7, an area for allowing an escape of the film such as the film escape recess is not formed any of the lower and upper mold dies 101 and 102, and the semiconductor device 1. This lack of a space allowing an escape of the releaser film 110 above the cavity 109 results in transmission of a pressing force from the upper mold die 102 to the seal glass 108 via the release film 110. Therefore, as illustrated in FIG. 7, the seal glass 108 has to receive a bending stress constituted by a compression stress at the upper surface side and a tension stress at the lower surface side. This structure has such a problem that the seal glass 108 may be broken when the bending stress at this time exceeds the strength of the seal glass 108.

On the other hand, as illustrated in FIG. 6, according to the present embodiment, a film escape recess 104b is formed at the surface of the cover glass 108 closer to the release film 110 over a portion of the seal glass 108 corresponding to the cavity 109, instead of forming the film escape recess at the mold die 100 (the upper die 102). This film escape recess 104b can be formed by, for example, mechanically cutting or scraping the portion of the cover glass 108 corresponding to the cavity 109 on the surface of the cover glass 108 closer to the release film 110, or etching the portion of the cover glass 108 corresponding to the cavity 109 by, for example, a chemical solution.

This film escape recess 104b has an area corresponding to the cavity 109 in a planar view, and a depth equal to or greater than a reduction in the thickness of the release film 110 when the semiconductor device 1 is clamped by the upper and lower dies 102 and 103 and the release film 110 is compressed, i.e., a depth equal to or greater than a value of a compression allowance (for example, a depth of approximately 0.3 mm to 0.5 mm).

Alternatively, the depth of the film escape recess 104b may be shallower than the compression allowance as long as a pressure applied from the release film 110 to the seal glass 108 above the cavity 109 during a clamping process falls within an allowable range.

Further, although it is preferable that the area of the film escape recess 104b corresponds to the area of the cavity 109 in a planar view, the area of the film escape recess 104b may be smaller than the area of the cavity 109 as long as a pressure applied from the release film 110 to the seal glass 108 above the cavity 109 during a clamping process falls within an allowable range. Further, the area of the film escape recess 104b may overlap the area occupied by the rib member or spacer 107 in a planar view as long as it is possible to prevent generation of a thin flash at the seal glass 108.

The structure according to the present embodiment can provide the same advantageous effect with the above-described embodiment including the film escape recess 104a formed at the mold die 100. More specifically, during a clamping process, the release film 110 escapes into the film escape recess 104b of the seal glass 108 at the portion corresponding to the cavity 109, thereby preventing transmission of a pressing pressure from the bottom surface of the cavity 103 of the upper die 102 to the seal glass 108, preventing application of a bending stress to the seal glass 108. Therefore, resin molding (resin sealing) can be realized by clamping the semiconductor device 1 by the mold die 100 (the upper die 102 and the lower die 101) at a pressure capable of preventing breakage of the seal glass 108 and generation of a thin flash at the seal glass 108. As a result, it is possible to improve the yield rate of the semiconductor device 1. Further, since the film escape recess 104b is formed at the seal glass 108, it is possible to reduce or prevent increases in the size and cost of the semiconductor device 1, compared to the conventional technique using the support frame disposed around the seal glass 108.

### Modification

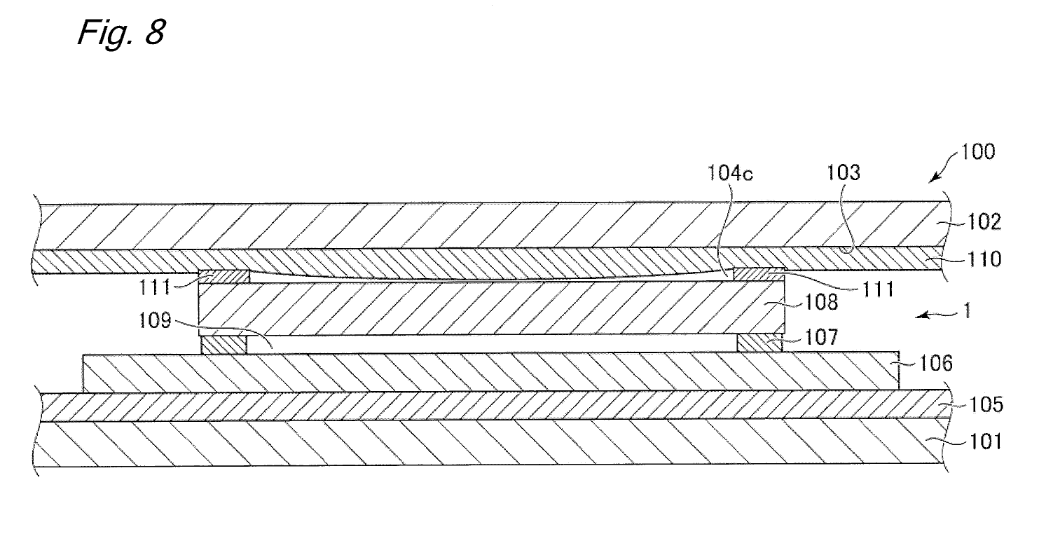

FIG. 8 is an enlarged cross-sectional view of a modification of the second embodiment, illustrating the mold die 100 and the semiconductor device 1 with a film escape area 104c defined as an area surrounded by a spacer member 111 disposed at the periphery of the seal glass 108. As illustrated in FIG. 8, the spacer member 111 having a predetermined thickness may be disposed on the seal glass 108 so as to surround the portion of the seal glass 108 corresponding to the cavity 109 on the surface of the seal glass 108 closer to the release film 110, instead of forming the film escape recess 104b on the surface of the seal glass 108 closer to the release film 110, and this portion surrounded by the spacer member 111 may be used as the film escape area 104c.

The film escape area 104c has an area corresponding to the cavity 109 in a planar view. Now, assuming that the depth of the film escape area 104c means a height difference between the portion surrounded by the spacer member 111 and the top surface of the spacer member 111 (i.e., the thickness of the spacer member 111), the depth of the film escape area 104c is equal to or greater than a reduction in the thickness of the release film 110 when the semiconductor device 1 is clamped by the upper and lower dies 102 and 103 and the release film 110 is compressed, i.e., a depth equal to or greater than a value of a compression allowance (for example, a depth of approximately 0.3 mm to 0.5 mm).

Alternatively, the depth of the film escape area 104c may be shallower than the value of the compression allowance as long as a pressure applied from the release film 110 to the seal glass 108 above the cavity 109 during a clamping process falls within an allowable range.

Further, although it is preferable that the film escape area 104c corresponds to the area of the cavity 109 in a planar view, the area of the film escape area 104c may be smaller than the area of the cavity 109 as long as a pressure applied from the release film 110 to the seal glass 108 above the cavity 109 during a clamping process falls within an allowable range. Further, the film escape area 104c may overlap the area occupied by the rib member or spacer 107 in a planar view as long as it is possible to prevent generation of a thin flash at the seal glass 108.

Although it is preferable that the spacer member 111 is disposed continuously along the whole circumference of the periphery of the seal glass 108, the spacer member 111 may be omitted at a part of the periphery of the seal glass 108 as long as a bending stress received by the seal glass 108 above the cavity 109 falls within an allowable range.

The spacer member 111 can be embodied by, for example, a film (for example, polyimide film; hereinafter referred to as “height difference generation film”) made of a more rigid material than the release film 110. In this case, for example, the height difference generation film approximately 0.3 mm to 0.5 mm high is attached to the periphery of the seal glass 108 by an adhesive agent or the like. The spacer member 111 is not limited to the film, and may be embodied by any arbitrary member having a desired thickness and rigidity.

In this way, formation of the film escape area 104c for allowing an escape of the release film 110 with use of the spacer member 111 such as the height difference generation film can also provide the same advantageous effect as the embodiment including the film escape recess 104b formed by partially reducing the thickness of the seal glass 108. Further, formation of the film escape area 104c by adding the space member 111 allows an existing seal glass to be used to easily realize the film release area. Further, it is possible to reduce or prevent increases in the size and cost of the semiconductor device 1, compared to the conventional technique using the support frame disposed around the seal glass 108.

As mentioned above, the a method for manufacturing a semiconductor device according to the above-described embodiments enables the semiconductor device to be clamped and molded at a pressure capable of preventing breakage of the seal glass and generation of a thin flash at the seal glass by eliminating application of a pressure of the release film to the central portion of the seal glass. As a result, it is possible to manufacture an excellent product without breakage of the glass and generation of a thin flash.

### REFERENCE SIGNS LIST

1 semiconductor device

100 mold die

101 lower mold die

102 upper mold die

103 cavity

104a, 104b film escape recess

104c film escape area

105 substrate (wiring board)

106 sensor chip

107 rib member or spacer

108 seal glass

109 cavity under glass

110 release film

111 space member

1. A method for manufacturing a semiconductor device, in which a resin is molded on a semiconductor device having a cavity inside a seal glass while protecting the seal glass of the semiconductor device with a release film, the method comprising:
molding a resin on the semiconductor device in such a state that the release film escapes in a film escape area formed at a mold die or the seal glass above the cavity when the semiconductor device is clamped by the mold die.

2. The method for manufacturing a semiconductor device according to claim 1, wherein the film escape area corresponds to an area occupied by the cavity.

3. The method for manufacturing a semiconductor device according to claim 1, wherein a depth of the film escape area is equal to or greater than a compression allowance by which the release film is compressed at a portion of the release film other than the cavity when the semiconductor device is clamped by the mold die.

4. The method for manufacturing a semiconductor device according to claim 1, wherein the film escape area comprises a film escape recess formed at the mold die.

5. The method for manufacturing a semiconductor device according to claim 1, wherein the film escape area comprises a film escape recess formed on a surface of the seal glass closer to the release film.

6. The method for manufacturing a semiconductor device according to claim 1, wherein a member having a predetermined thickness is disposed on a surface of the seal glass closer to the release film so as to surround at least a part of the area corresponding to the cavity, and a portion surrounded by the member is used as the film escape area.

7. The method for manufacturing a semiconductor device according to claim 6, wherein the member having the predetermined thickness is a more rigid film than the releaser film.

8. The method for manufacturing a semiconductor device according to claim 1, wherein the seal glass is disposed on a semiconductor chip via a rib member or spacer, by which the cavity is defined.

9. The method for manufacturing a semiconductor device according to claim 1, wherein the semiconductor device comprises an image sensor such as a CCD image sensor or a CMOS image sensor.

10. A resin sealing apparatus for molding a resin on a semiconductor device having a cavity inside a seal glass while protecting the seal glass of the semiconductor device with a release film, the resin sealing apparatus comprising:
a film escape recess allowing an escape of the release film when the semiconductor device is clamped by a mold die, the film escape recess being formed at the mold die so as to at least partially overlap an area occupied by the cavity.

11. The resin sealing apparatus according to claim 10, wherein an area occupied by the film escape recess corresponds to an area occupied by the cavity.

12. The resin sealing apparatus according to claim 10, wherein a depth of the film escape recess is equal to or greater than a compression allowance by which the release film is compressed at a portion of the release film other than the cavity when the semiconductor device is clamped by the mold die.

13. A semiconductor device having a cavity inside a seal glass, the semiconductor device being manufactured by molding a resin on the semiconductor device while protecting the seal glass of the semiconductor device with a release film, the semiconductor device comprising:
a film escape area allowing an escape of the release film when the semiconductor device is clamped by a mold die, the film escape area being formed at the seal glass so as to at least partially overlap an area occupied by the cavity.

14. The semiconductor device according to claim 13, wherein an area occupied by the film escape area corresponds to an area occupied by the cavity.

15. The semiconductor device according to claim 13, wherein a depth of the film escape area is equal to or greater than a compression allowance by which the release film is compressed at a portion of the release film other than the cavity when the semiconductor device is clamped by the mold die.

16. The semiconductor device according to claim 13, wherein the film escape area comprises a film escape recess formed on a surface of the seal glass closer to the release film.

17. The semiconductor device according to claim 13, wherein a member having a predetermined thickness is disposed on a surface of the seal glass closer to the release film so as to surround at least a part of the area corresponding to the cavity, and a portion surrounded by the member is used as the film escape area.

18. The semiconductor device according to claim 17, wherein the member having the predetermined thickness is a more rigid film than the releaser film.

19. The semiconductor device according to claim 13, wherein the seal glass is disposed on a semiconductor chip via a rib member or spacer, by which the cavity is defined.

20. The semiconductor device according to claim 13, further comprising an image sensor such as a CCD image sensor or a CMOS image sensor.
